(19) United States
(12) Patent Application Publication
(10) Pub. No.: US 2026/0050043 A1
(43) Pub. Date: Feb. 19, 2026

(54) METHOD AND SYSTEM FOR ESTIMATING THE AVAILABLE STATE OF CHARGE OF A BATTERY ACCORDING TO THE INSTANTANEOUS VOLTAGE

(71) Applicants: SAFRAN ELECTRICAL & POWER, BLAGNAC (FR); UNIVERSITE DE TECHNOLOGIE DE COMPIEGNE, COMPIEGNE (FR); CENTRE NATIONAL DE LA RECHERCHE SCIENTIFIQUE (CNRS), Paris (FR)

(72) Inventors: Fernanda VENDRAME, MOISSY-CRAMAYEL (FR); Marie SAYEGH, MOISSY-CRAMAYEL (FR); Christophe FORGEZ, COMPIEGNE (FR)

(73) Assignees: SAFRAN ELECTRICAL & POWER, BLAGNAC (FR); UNIVERSITE DE TECHNOLOGIE DE COMPIEGNE, COMPIEGNE (FR); CENTRE NATIONAL DE LA RECHERCHE SCIENTIFIQUE (CNRS), Paris (FR)

(21) Appl. No.: 18/859,694

(22) PCT Filed: Apr. 17, 2023
(86) PCT No.: PCT/FR2023/050547

§ 371 Date: Oct. 24, 2024

(30) Foreign Application Priority Data
Apr. 27, 2022 (FR) FR2203955

(51) Int. Cl. G01R 31/3842; G01R 31/374; H01M 10/42

(52) U.S. Cl. CPC G01R 31/3842; G01R 31/374; H01M 10/4285

(57) ABSTRACT

A method for estimating the state of charge of a battery, the method comprising the following steps: determining the stored state of charge; determining the open-circuit instantaneous voltage of the battery according to a predetermined map and the stored state of charge; measuring the instantaneous voltage across the terminals of the battery; determining the available state of charge according to the stored state of charge, the instantaneous voltage, the open-circuit instantaneous voltage and the minimum acceptable voltage; and the minimum acceptable voltage being predetermined by design.

### TECHNICAL FIELD

The invention relates to the technical field of electric batteries, and more particularly to the estimation of the state-of-charge of such batteries.

### PRIOR ART

The state-of-charge SOC (English acronym standing for “State-of-Charge”) of a battery indicates the amount of charge present in the battery. It may be expressed as an absolute value (Ah) or as a relative value relative to the maximum charge that the battery could have (%). The state-of-charge SOC is not a measurable quantity, therefore, it should be estimated based on the available measurements (current, voltage, temperature).

The method most commonly used to calculate the state-of-charge SOC is coulombmeter counting, which consists in integrating the current over time. This is applicable when the initial state-of-charge SOC is known. Hence, the state-of-charge SOC at a time point t is expressed (in Ah) by:

$${SOC}_{stored} ( t ) = {SOC}_{stored , 0} + \frac{1}{3600} {\int }_{0}^{t} I ( t ) dt \qquad [ Eq . 1 ]$$

If one wishes to express it as a percentage SOC_{stored_relative}, all it needs is to divide it by the maximum state-of-charge SOCₘₐₓ of the battery.

$${SOC}_{stored \_ relative} ( t ) = 100 \frac{{SOC}_{stored} ( t )}{{SOC}_{max}} \qquad [ Eq . 2 ]$$

The state-of-charge SOC_{stored} estimated by coulombmeter counting gives information on the capacity stored in the battery. Yet, it is dangerous to rely on this information alone because part of this capacity could potentially be unavailable, especially at low temperature and/or high current. These available capacity variations result from the variations of the internal impedance of the battery. When a discharge current flows through the battery, the voltage across the terminals of the battery decreases proportionally to the impedance of the battery and to the current between its terminals.

FIG. 1 shows the evolution of the voltage across the terminals of the battery over time during a discharge at the current 1 C at two different temperatures, 10° C. and 25° C. The curves in bold lines are associated with the temperature 25° C. whereas the curves in thin line are associated with the temperature 10° C. The impedance of the battery increases when the temperature decreases, therefore the resulting voltage drop is higher. Similarly, if the impedance is the same, the voltage drop will be higher for a higher current. It is important to note that the discharge of the battery stops when the lowest acceptable voltage is reached. Yet, for the same stored state-of-charge SOC_{stored}, this voltage is reached more rapidly if the current is high or if the temperature is low. Under these circumstances, the available state-of-charge SOC_{available} is lower.

In this context, it becomes essential to determine the difference between the stored state-of-charge SOC_{stored} and the available state-of-charge SOC_{available}. The available state-of-charge SOC_{available} theoretically depends on the stored state-of-charge SOC_{stored}, the temperature T and the current I:

$${SOC}_{available} = f ( {SOC}_{stored} , T , I ) \qquad [ Eq . 3 ]$$

A technical problem to be solved consists in determining the function between the available state-of-charge SOC_{available}, the current and the temperature or in finding another means for taking account of the effects of the current and of the temperature on the available state-of-charge SOC_{available}.

As regards the temperature, it is possible to perform a series of charging and discharge tests of the battery at a sufficiently low current (so as not to heat up the battery during the test) to obtain the limit values of the charge stored in the battery. FIG. 2 illustrates the available capacity of the battery as a function of the temperature, and with regards to the charging or discharge operations. The area 1 corresponds to the unavailable capacity in charging as a function of the temperature. The area 3 corresponds to the unavailable capacity in discharge as a function of the temperature. The area 2 corresponds to the available capacity in charging and in discharge as a function of the temperature. For example, at the end of discharge at a temperature of 0° C., about 0.24 Ah remain stored in the battery and are not available during discharge. Thus, one could deduce that the available state-of-charge SOC_{available} at 0° C. is lower than the stored state-of-charge SOC_{stored} by 0.24 Ah.

However, this approach cannot be adopted to study the dependence of the available capacity on the current, because the strong currents heat up the battery and the measured capacity value cannot therefore be associated with a specific operating point.

One approach that allows modelling the available capacity variation with the current is the kinetic model, illustrated in FIG. 3. The right reservoir contains y1, which corresponds to the available charge/energy. Its width is c, smaller than 1. The level of this reservoir is h1, which represents the state-of-charge SOC/the state-of-energy SOE. The left reservoir contains y2, which is the load charge/energy. Its width is 1-c and its level is h2. When a load is applied (a current I when talking about a charge reservoir or a power P when talking about an energy reservoir), the level of the right reservoir decreases. At the same time, the charge/energy can pass from the left reservoir to the right one throughout a valve k′, which means that the flow rate at the inlet of the right reservoir is always lower than that at the outlet. The higher the applied load, the faster the level difference between the two reservoirs will increase. Hence, the unavailable charge/energy is (1−c)*(h1-h2). However, as soon as the load stops, the level of the right reservoir starts increasing, which is so-called recovery of the charge/energy. This behaviour is similar to the diffusion that occurs in the battery. Indeed, when a high load is applied, the overvoltage (difference between the cell voltage and its open-circuit voltage OCV (English acronym standing for “Open-Circuit Voltage”)) can significantly increase and if the voltage of the battery is already close to its lower limit, the discharge may be interrupted. However, this discharge could quite well be carried on at a lower current/power and one could even imagine that an infinitesimal current/power could completely discharge the battery.

The Equations that Govern this Model are as Follows:

$$\{ \begin{matrix}\frac{{dy}_{1}}{dt} = - I - {k}^{′} ( {h}_{1} - {h}_{2} ) \\ \frac{{dy}_{2}}{dt} = {k}^{′} ( {h}_{1} - {h}_{2} )\end{matrix} \qquad [ Eq . 4 ]$$

To parametrise this model, it is necessary to generate profiles at different currents and temperatures based on the electrical model of the battery and to use an optimisation algorithm to find, at each temperature, a pair (k′, c) which allows obtaining y1=0 at the end of discharge at each current. Afterwards, these two parameters allow obtaining Ymax, which is the maximum capacity/energy that could be stored in the battery at the considered temperature.

Unfortunately, this model has a high level of complexity, and its parameterisation depends on the quality of the profiles obtained from the electrical model. Hence, we have errors of the electrical model and parameterisation errors of the kinetic model which accumulate.

To sum up, the available charge in a battery is different from the stored charge and depends on the temperature and the electrical current. It is possible to estimate the available charge in a battery at different temperatures and at a low constant current. However, this cannot be done for high currents because they significantly increase the temperature of the battery, which prevents having a measurement of the available charge at a given temperature for different currents. Yet, the voltage of the battery is directly influenced by the temperature and the current. Moreover, the voltage is the main criterion of stoppage of a discharge. Hence, this information can be used to find the available state-of-charge SOC from the stored SOC.

There is a need for a method for determining the available state-of-charge of a battery allowing taking account of the effect of the temperature and of the current, even for high currents.

From the prior art, document US2022/065934 is known disclosing a battery system comprising a battery and a device for estimating the state of the battery according to a model.

The prior art does not address the need identified hereinabove because the available models are either incomplete or difficult to parametrise.

### DISCLOSURE OF THE INVENTION

An object of the invention is a method for estimating the state-of-charge of a battery comprising the following steps:
determining the stored state-of-charge,
determining the open-circuit instantaneous voltage of the battery according to a predetermined map, the stored state-of-charge, and the temperature,
measuring the instantaneous voltage across the terminals of the battery,
determining the available state-of-charge according to the stored state-of-charge, the instantaneous voltage, the open-circuit instantaneous voltage and a minimum acceptable voltage,
the minimum acceptable voltage being a piece of data predetermined by design, and
to determine the available state-of-charge, the product of the stored state-of-charge by the ratio between the difference between the instantaneous voltage and the minimum acceptable voltage and the difference between the open circuit voltage and the minimum acceptable voltage may be computed.
the determination of the stored state-of-charge may be carried out by carrying out the following steps: the determination the stored state-of-charge is carried out by carrying out the following steps:
   measuring the open-circuit voltage of the battery at rest
   determining the initial stored state-of-charge according to a table relating the initial stored state-of-charge to the open-circuit voltage at rest of the battery and to the temperature,
   using the battery in charging and/or in discharge,
   periodically measuring the instantaneous current,
   integrating the measured instantaneous current from the start of use after each measurement of the instantaneous current, and
   determining the stored state-of-charge as the sum of the result of the integration and of the value of the initial stored state-of-charge.

The determination of the stored state-of-charge may also be carried out by a Kalman observer with a state vector defined by the stored state-of-charge and a diffusion voltage, the output vector being the instantaneous voltage of the battery

The future available state-of-charge of a battery may be determined as being equal to the determined available state-of-charge when the instantaneous voltage of the battery is a future voltage.

Another object of the invention is a system for estimating the state-of-charge of a battery comprising data processing means, at least one memory, at least one means for measuring the voltage across the terminals of the battery, and at least one means for measuring the current flowing between the terminals of said battery, the data processing means being configured to carry out the determination method steps as described hereinabove.

### BRIEF DESCRIPTION OF THE DRAWINGS

Other aims, features and advantages of the invention will appear upon reading the following description, given solely as a non-limiting example and made with reference to the appended drawings wherein:

FIG. 1 illustrates an example of discharge of a current battery 1 C at two different temperatures,

FIG. 2 illustrates the capacity stored at the end of charging and at the end of discharge as a function of the temperature,

FIG. 3 illustrates the kinetic model of discharge of a battery,

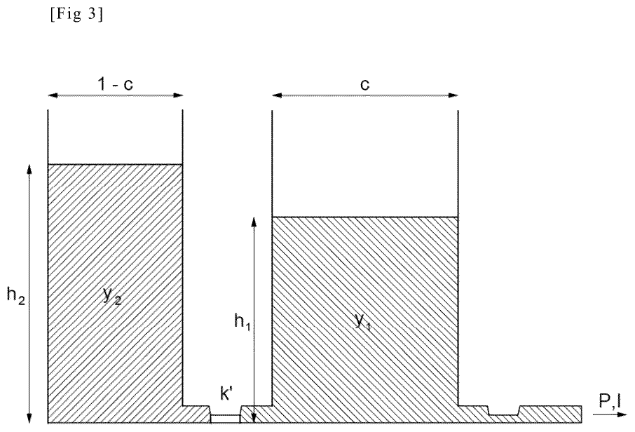

FIG. 4 illustrates the comparison of the evolution of the state-of-charge as a function of time for a continuous discharge at 3 C and 0° C. according to several determination methods.

### DETAILED DESCRIPTION

As set out in the introduction, the voltage of the battery is directly influenced by the current and the temperature. The higher the current, the higher the voltage variation will be. The contribution of the temperature is inverse so that the lower the temperature, the more significant the electrical resistances and the voltage variation will be. Hence, it is possible to use the voltage to calculate the available state-of-charge SOC_{available}. In this case, as soon as the voltage reaches a limit value resulting in stoppage of discharge, the available state-of-charge SOC_{available} should be zero. This is met by the equation [Eq. 5] hereinbelow.

The state-of-charge estimation method according to the invention is based on this observation.

The initial stored state-of-charge SOC_{stored,0} is determined according to the open-circuit voltage OCV (acronym for “Open-Circuit Voltage”) and the temperature, when the battery is at rest and relaxed. By “battery at rest and relaxed”, it should be understood a battery, the use of which is interrupted for a period of time that is long enough for the voltage of the battery to reach the open-circuit voltage OCV and the temperature of the battery to reach room temperature

During the discharge, the current is measured periodically and then integrated after each current measurement from the start of the discharge in order to determine the stored state-of-charge SOC_{stored}, by coulombmeter counting by application of the equation [Eq. 1].

Alternatively, the stored state-of-charge SOC_{stored} is determined by a Kalman observer estimation.

The Kalman observer estimates at each time point the value of the state variables according to their value at the previous time point and the inputs of the system. Afterwards, the output of the system is calculated according to these state variables and compared with a measured value. Depending on the observed discrepancy and the settings of the filter, a more or less high correction factor is applied to the state variables. Hence, this amounts to adjusting these variables which cannot be measured so that the output, which depends on these variables, is consistent with a variable that can be measured.

$$The state vector x is x = \{ \begin{matrix}{SOC}_{stored} \\ {U}_{diff}\end{matrix}$$

With SOC: the state-of-charge of the battery, and Udiff: the internal voltage which reflects the dynamic diffusion phenomena, which is an integral part of the battery voltage such that:

$$Udiff + OCV + {R}_{S} * I = U ( t )$$

With Rs*I the internal voltage related to static phenomena and Rs the associated resistance.
The control vector u is u={I}
With I: the charging or discharge current
The equation of state is then as follows:

$${x}_{k + 1} = A \cdot {x}_{k} + B \cdot {u}_{k}$$

With A and B: two matrices of coefficients
The output vector is y={U(t)}
With U(t): the overall voltage of the battery at the time point t
   The Output of the System is then as Follows:

$${y}_{k + 1} = C \cdot {x}_{k} + D \cdot {u}_{k}$$

With C and D: Two Matrices of Coefficients

The Kalman filter is initialised by the covariance matrix method, with a covariance matrix R of the process noise, a covariance matrix Q of the observation noise and a state error covariance matrix P. The matrices R and Q may remain constant throughout the observation, whereas the matrix P is recalculated at each time point.

Based on the determination of the stored state-of-charge SOC_{stored} and irrespective of the used method for estimating the stored state-of-charge SOC_{stored}, the available state-of-charge SOC_{available} is calculated by application of the following equation:

$${SOC}_{available} ( t ) = {SOC}_{stored} ( t ) \cdot \frac{U ( t ) - {U}_{min}}{OCV ( t ) - {U}_{min}} \qquad [ Eq . 5 ]$$

### With:

SOC_{stored}: the stored state-of-charge SOC.
U(t): the overall voltage of the battery at the time point t, and
Uₘᵢₙ: the minimum acceptable voltage, which defines the end of discharge.
OCV(t): the open-circuit voltage at the time point t

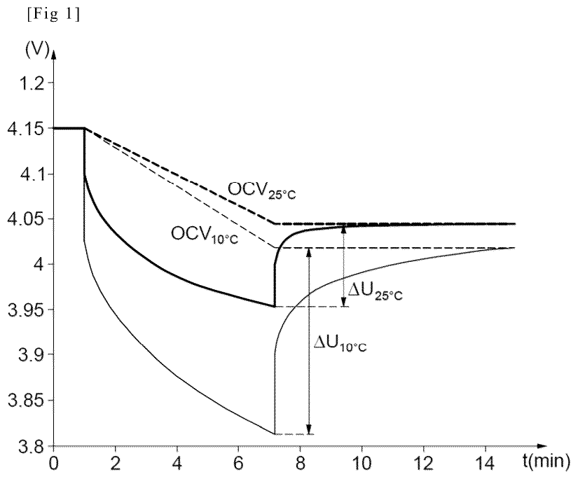

It will be noted that the open-circuit voltage at the time point t OCV(t) varies at each time point. It should be recalled that the open-circuit voltage OCV is determined as the voltage of the battery when it is not connected to any load or power source. One could then understand that the open-circuit voltage OCV cannot be determined during the use of the battery. A map of the open-circuit voltage OCV(t) is then used according to the stored state-of-charge SOC_{stored} (t) and the temperature of the battery T. The map is determined by testing by measuring the voltage OCV for different stored states-of-charge SOC_{stored} and for different temperatures T. An example of such a map is illustrated by broken lines in FIG. 1.

The minimum voltage Uₘᵢₙ is a manufacturer piece of data related to the battery.

With equation [Eq. 5], it is possible to take account of both the effects of the current and of the temperature. In this case, it is assumed that the available state-of-charge SOC_{available} is equal to the stored state-of-charge SOC_{stored} when the battery is at rest (U=OCV), irrespective of the temperature. As soon as a load is applied on the battery, the produced overvoltage U(t)-OCV(t) (and therefore the reduction in the available SOC) is even higher as the resistance is high and therefore as the temperature is low. The overvoltage is also even higher when the current is high.

This estimation method is such that the available state-of-charge SOC_{available} decreases and increases according to the same aspect of the voltage. Hence, this method allows providing for the discharge cut-offs very effectively, because the available state-of-charge SOC_{available} is always zero when the voltage reaches its limit value and that being so, even though the stored state-of-charge SOC_{stored} has been poorly initialised.

Thus, the method for estimating the state-of-charge according to the invention comprises the following steps:

During a first step, the stored state-of-charge SOC_{stored} (t) is determined and the open-circuit instantaneous voltage OCV(t) of the battery is determined according to the stored state-of-charge SOC_{stored} (t) and the temperature of the battery T.

During a second step, the instantaneous voltage U(t) across the terminals of the battery is measured.

During a third step, the available state-of-charge SOC_{available} (t) is determined according to the stored state-of-charge SOC_{stored} (t), the instantaneous voltage U(t), the open-circuit instantaneous voltage OCV(t) and the minimum acceptable voltage Uₘᵢₙ by applying the equation [Eq. 5].

The minimum acceptable voltage Uₘᵢₙ is a predetermined manufacturer piece of data.

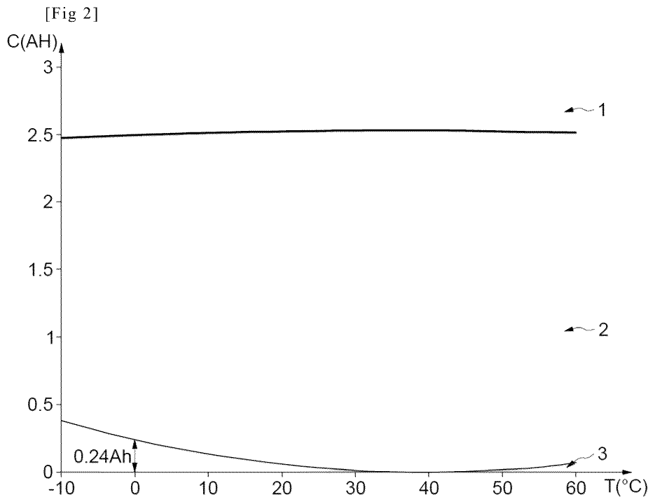

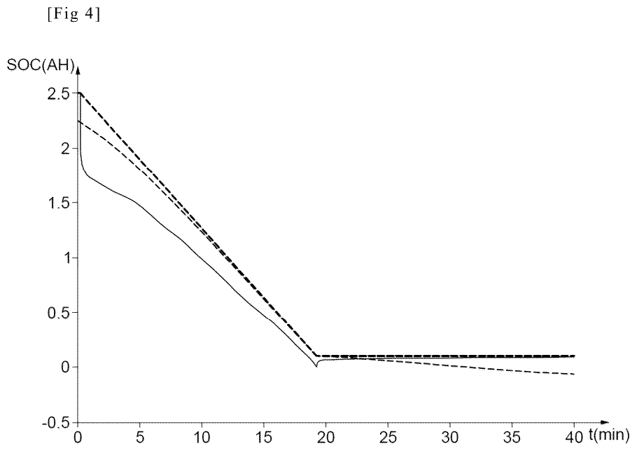

FIG. 4 shows results of the method for estimating the state-of-charge according to the invention for a continuous discharge at 3 C and 0° C. The curve in bold and dashed line corresponds to the stored state-of-charge SOC_{stored}, the curve in light and dashed line corresponds to the available state-of-charge SOC_{available} obtained with a method that takes account of the temperature but not of the current (cf. FIG. 2) and the curve in continuous line corresponds to the available state-of-charge SOC_{available} obtained by the method according to the invention. Unlike the other ones, this method clearly indicates that the state-of-charge SOC at the end of discharge is 0 Ah. Moreover, this method allows estimating as of the start of the profile that the available state-of-charge SOC decreases substantially because of the high current.

In another embodiment, instead of using the measured voltage U(t) to determine the available state-of-charge SOC, it is possible to use a simulated voltage corresponding to a future voltage. The available state-of-charge SOC is then equal to the available state-of-charge SOC at said future time for a given current or power profile corresponding to the future voltage.

This method, described to estimate the available state-of-charge SOC, could also be applied to the SOE (State-of-Energy). The use of the state-of-charge SOC is preferred in order to determine the charge of the battery when a current is imposed. The state-of-energy, which is related to the available power and indirectly to the losses of the system, in particular thermal losses, is preferred when a power is imposed on the battery.

Hence, the state-of-charge estimator allows accurately estimating the available state-of-charge SOC while taking account of the effects of the current and of the temperature.

The method for estimating the available state-of-charge of a battery has been described hereinabove in connection with the discharge of a battery. Nevertheless, a person skilled in the art will easily understand that the described method could be applied indifferently to a battery in charging, in discharge or subjected to a combination of chargings and discharges.

1. A method for estimating the state-of-charge of a battery, comprising:
determining the stored state-of-charge;
determining the open-circuit instantaneous voltage of the battery according to a predetermined map, the stored state-of-charge, and a temperature;
measuring the instantaneous voltage across the terminals of the battery; and determining the available state-of-charge according to the stored state-of-charge, the instantaneous voltage, the open-circuit instantaneous voltage, and a minimum acceptable voltage,
wherein the minimum acceptable voltage is a piece of data predetermined by design, and
wherein determining the available state-of-charge includes computing the product of the stored state-of-charge by the ratio between the difference between the instantaneous voltage and the minimum acceptable voltage and the difference between the open circuit voltage and the minimum acceptable voltage.

2. The method according to claim 1, wherein determining the stored state-of-charge comprises:
using the battery in charging and/or in discharge;
periodically measuring the instantaneous current;
integrating the measured instantaneous current from the start of use after each measurement of the instantaneous current; and
determining the stored state-of-charge as the sum of the result of the integration and of the value of the initial stored state-of-charge.

3. The method according to claim 1, wherein determining the stored state-of-charge is carried out by a Kalman observer having:
a state vector defined by the stored state-of-charge and a diffusion voltage; and
an output vector defined as the instantaneous voltage of the battery.

4. The method according to claim 1, wherein the future available state-of-charge of a battery is determined as being equal to the determined available state-of-charge when the instantaneous voltage of the battery is a future voltage.

5. A system for estimating the state-of-charge of a battery, the system comprising:
data processing means;
at least one memory;
at least one means for measuring the voltage across the terminals of the battery; and
at least one means for measuring the current flowing between the terminals of battery, wherein the data processing means is configured to carry out the determination method steps of claim 1.
